(19) United States
(12) Patent Application Publication
(10) Pub. No.: US 2026/0011558 A1
(43) Pub. Date: Jan. 8, 2026

(54) GAP FILL METHODS IN HIGH ASPECT RATIO FEATURES

(71) Applicant: Applied Materials, Inc., Santa Clara, CA (US)

(72) Inventors: Sai Hooi Yeong, Cupertino, CA (US); Xiang Ji, Sunnyvale, CA (US); Lisa McGill, Hillsboro, OR (US); Praket P. Jha, San Jose, CA (US); Jingmei Liang, San Jose, CA (US); Benjamin Colombeau, San Jose, CA (US); Balasubramanian Pranatharthiharan, San Jose, CA (US); Raghuveer Satya Makala, Campbell, CA (US)

(73) Assignee: Applied Materials, Inc., Santa Clara, CA (US)

(21) Appl. No.: 18/762,072

(22) Filed: Jul. 2, 2024

(51) Int. Cl. H01L 21/225; H01L 21/8234; H01L 27/088; H01L 27/092; H01L 29/06; H01L 29/423; H01L 29/66; H01L 29/775; H01L 29/78; H01L 29/786

(52) U.S. Cl. CPC H01L 21/2254; H10D 30/014; H10D 30/43; H10D 30/6735; H10D 30/6757; H10D 62/121; H10D 64/017; H10D 84/0128; H10D 84/038; H10D 84/83; H10D 30/024; H10D 30/62; H10D 84/0158; H10D 84/853

(57) ABSTRACT

Described are semiconductor devices, e.g., PMOS and/or NMOS, with improved stress in the channel region. The semiconductor devices include a substrate, a source region, a drain region, a channel extending between the source region and the drain region, and a diffusion break patterned through the device. The self-aligned diffusion break opening is gap filled a stressed dielectric material using a densified seam-free silicon-containing material gap fill process.

### TECHNICAL FIELD

Embodiments of the present disclosure generally relate to semiconductor devices and, more particularly, to methods for filling high aspect ratio features of FinFET, Gate All Around (GAA), and CFET devices.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a gate all around (GAA) structure. Logic gate performance is related to the characteristics of the materials used as well as the thickness and area of the structural layers. However, as some gate characteristics are adjusted to accommodate device scaling, challenges arise.

As device sizes continue to reduce, film characteristics may lead to larger impacts on device performance. As devices shrink and more complex patterning schemes are utilized in the industry, deposition of thin films becomes a challenge. In addition, as material thicknesses continue to reduce, as-deposited characteristics of the films may have a greater impact on device performance. These challenges include depositing seam free and/or void free films in high aspect ratio features.

Thus, there is a need in the art for logic devices having high quality films that are free of intrinsic seams and voids.

### SUMMARY

One or more embodiments of the disclosure are directed to methods of forming a semiconductor device. In one or more embodiments, a method of forming a semiconductor device comprises: etching a diffusion break in a gate region of a semiconductor device, the diffusion break including a bottom surface and a sidewall surface, the gate region comprising an active region, the semiconductor device including a substrate, a source region, a drain region, and a channel extending between the source region and the drain region; flowing a silicon-containing precursor and a carrier gas over the substrate to form a silicon-containing layer on the bottom surface of the diffusion break; flowing a hydrogen-containing precursor over the silicon-containing layer to form a modified silicon-containing layer; etching the modified silicon-containing layer from the sidewall of the diffusion break; and reacting the modified silicon-containing layer with one or more radicals generated by a remote plasma source to form a silicon nitride (SiN) dielectric layer that at least partially fills the diffusion break.

Further embodiments of the disclosure are directed to methods of forming a semiconductor device. In one or more embodiments, a method of forming a semiconductor device comprises: etching a diffusion break in a gate region of a semiconductor device, the diffusion break including a bottom surface and a sidewall surface, the gate region comprising an active region, the semiconductor device including a substrate, a source region, a drain region, and a channel extending between the source region and the drain region; forming plasma effluents of a silicon-containing precursor and flowing the plasma effluents of the silicon-containing precursor over the substrate to form a silicon-containing layer on the bottom surface of the diffusion break; forming plasma effluents of a hydrogen-containing precursor and flowing the plasma effluents of the hydrogen-containing precursor over the silicon-containing layer to form a modified silicon-containing layer; etching the modified silicon-containing layer from the sidewall of the diffusion break; densifying remaining modified silicon-containing layer within the diffusion break; and reacting the modified silicon-containing layer with one or more radicals generated by a remote plasma source to form a silicon nitride (SiN) dielectric layer that at least partially fills the diffusion break.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method for forming a semiconductor device in accordance with some embodiments of the present disclosure;

FIG. 2A illustrates a cross-sectional view of a semiconductor device according to the prior art;

FIG. 2B illustrates a cross-sectional view of an exemplary semiconductor device according to one or more embodiments of the present disclosure;

FIGS. 3A-3D illustrate cross-sectional views of exemplary semiconductor structures according to one or more embodiments of the present disclosure;

FIGS. 4A-4C illustrate enlarged cross-sectional views of a portion of an exemplary semiconductor device according to one or more embodiments of the present disclosures;

FIGS. 5A-5C illustrate enlarged cross-sectional views of a portion of an exemplary semiconductor device according to one or more alternative embodiments of the present disclosure; and

FIG. 6 illustrates a schematic top-view diagram of an example multi-chamber processing system according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas”, and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

One example of gate-all-around (GAA) technology is complementary field effect transistor (CFET). As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors. CFET transistors have increased on-chip device density and reduced area consumption when compared to GAA transistors.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

In conventional technologies, the stress level in the MOSFET channel may be controlled by altering the composition of the semiconductor materials in the channel, as well as the compositions of the materials in the adjacent source and drain regions. In many instances, changes to the compositions of these doped regions of the transistor to give the channel region a desired amount of stress can lead to less desirable transistor performance in other respects, such as a lower thermal budget and/or an increased resistance at the interface between the contact and the doped region. Controlling channel region stress by altering the composition of the doped regions also limits the types of materials that can be used in the doped regions. For example, modern PMOS transistors often use a doped silicon-germanium (SiGe) semiconductor in the doped regions of the transistor. When the Ge-to-Si ratio gets too high, lattice mismatches create faults in the material that can reduce the channel region stress below an acceptable level.

Another conventional method for increasing the stress in a channel region of a transistor is depositing a stressed conductive material in the contact trench above the channel region. The stress from the conductive material is transmitted down to impart the required stress in the doped material of the channel region. These conventional methods also require careful selection and deposition of the conductive material in the contact trench to meet the stress requirements as well as the electrical conductivity, chemical reactivity, hermeticity, thermal budget, and other requirements for the material. In many instances, there must be a compromise in selecting a conductive material with less-than-ideal characteristics in some respects in order to satisfy the stress requirement. Changes in the deposition method or composition of the stressed material to create additional stress diminishes the performance of the material in other respects, such as electrical conductivity.

Conventional methods have proven more and more ineffective with the rise of increasingly complicated gate and channel surface orientations. Namely, the gate orientation of multi-channel semiconducting nanostructures, such as gate-all-around, complementary FET, nanosheet, and nanowire orientations, as examples only, hinder the effectiveness of conventional stress applications. As one example, conventional methods for increasing stress may apply adequate stress at an upper and/or lower gate but fails to provide the necessary stress on gates disposed therebetween. Furthermore, due at least in part to poor stress consistency in addition to unfavorable surface orientations, multi-channel semiconducting nanostructures also exhibit unfavorable hole and/or electron mobility. Such hole mobility deficiencies are particularly apparent in comparison to traditional gate and favored channel orientations, such as fin field-effect transistors (FinFET).

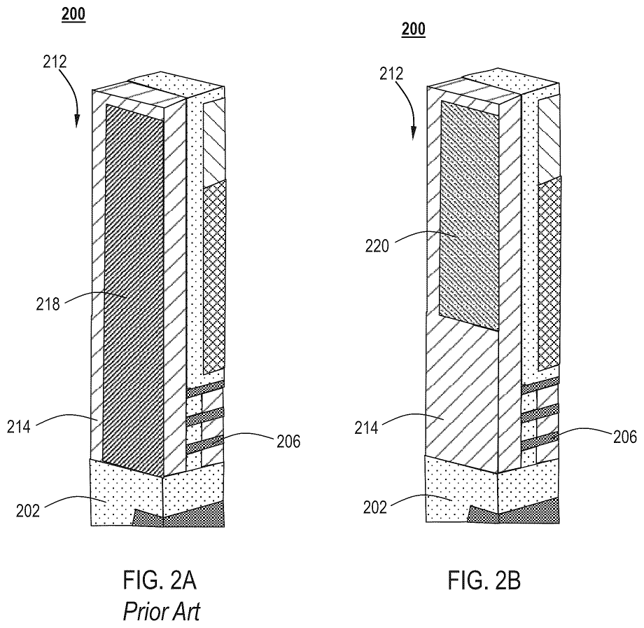

Efforts to improve channel strain in multi-channel semiconducting nanostructures in particular include source and drain regions formed via an epitaxial growth process. Due to the complex geometries and surface orientations, however, particularly in p-type metal oxide semiconductor (PMOS) regions, epitaxial merging consistently suffers from dislocations during and after formation. Such dislocations can pull the epitaxially grown material away from the gates, as well as create dislocation seams, leading to a relaxation in the channel stress over time. Methods have sought to improve epitaxial merge defects as a method to impart consistent channel stress. While newer methods have proven sufficient to provide consistent stress and/or improve electron and hole mobility, sufficient gap fill without noticeable seams/voids can be provided for diffusion break openings having an aspect ratio of less than 8. In one or more embodiments, the diffusion break opening may be a single diffusion break (SDB) or may be a double diffusion break (DDB). As illustrated in FIG. 2A according to the prior art, with a semiconductor device 200 having an aspect ratio greater than 8, however, the gap fill 214 in a diffusion break opening 212 results in the formation of intrinsic seams/voids 218 across the active device/nanosheet region 206.

In one or more embodiments, as illustrated in FIG. 2B, a semiconductor device is provided that advantageously has substantially no void/intrinsic seam 220 in the diffusion break opening gap fill 214 across the active device/nanosheet region 206 leading to improved stress in the channel region. Methods of producing such a device are also described. In one or more embodiments, the semiconductor device, e.g., a PMOS device, an NMOS device, or a wafer having both a PMOS device and an NMOS device thereon, comprises a substrate having a top surface; a source region having a source and a source contact, the source region on the top surface of the substrate; a drain region having a drain and a drain contact, the drain region on the top surface of the substrate; a channel located between the source and the drain; a gate enclosing the channel between the source region and the drain region. The gate includes a diffusion break opening in an active region and contains a stressed dielectric material having a compressive stress. In one or more embodiments, the diffusion break has a bottom surface and at least one sidewall surface. In some embodiments, the diffusion break has an aspect ratio of greater than 10. As used herein, the term “aspect ratio” refers to the ratio of the depth (or height) of the opening to the width of the opening. In some embodiments, the aspect ratio of the diffusion break is greater than or equal to about 10:1, 15:1, 20:1, 25:1, 30:1, 35:1 or 40:1. In one or more embodiments, the aspect ratio is greater than 25:1.

Although the disclosure will routinely identify specific metal-oxide semiconductor field-effect transistors (MOSFET), complementary metal-oxide semiconductors (CMOS), and components thereof, it will be readily understood that the device and methods are equally applicable to other field-effect transistors, orientations thereof, as processes for forming such devices. Accordingly, the technology should not be considered to be so limited as for use with these specific devices or methods alone. The disclosure will discuss one possible semiconductor device that may include one or more components, utilizing one or more diffusion break according to embodiments of the present technology before additional variations and adjustments to this apparatus according to embodiments of the present technology are described.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

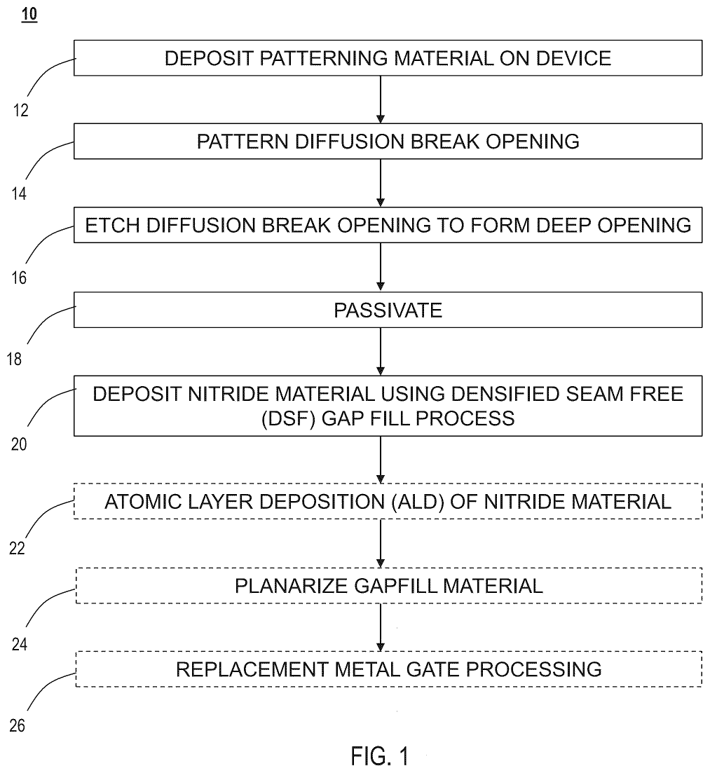

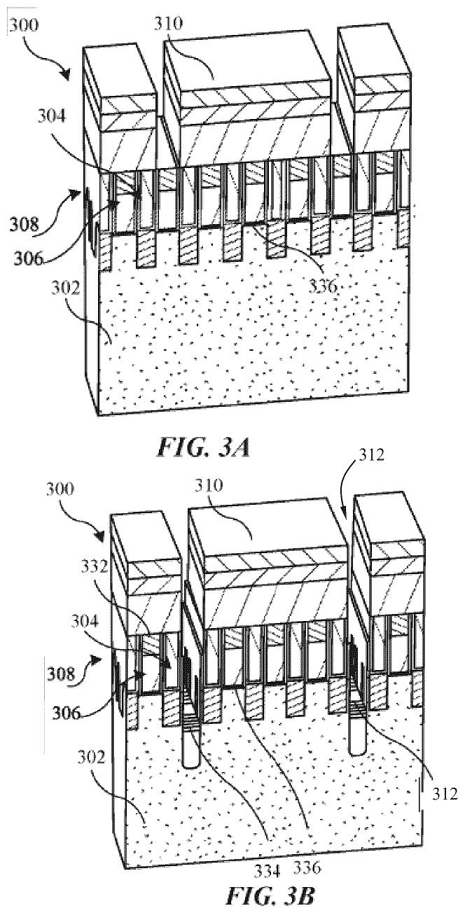

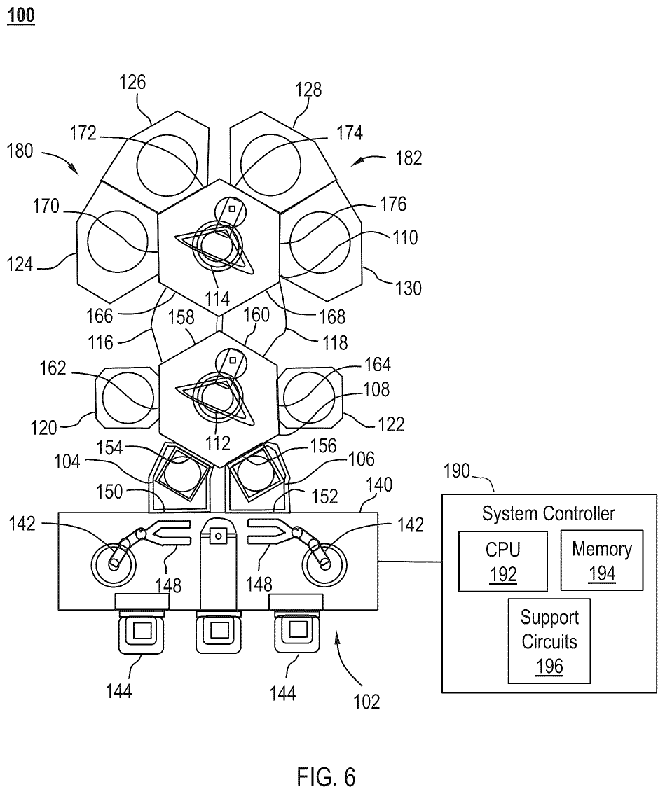

FIG. 1 illustrates a process flow diagram for a method 10 for forming a semiconductor device in accordance with some embodiments of the present disclosure. The method 10 may be performed in a variety of processing chambers known to the skilled artisan. Method 10 may include additional operations prior to initiation of the listed operations. For example, additional processing operations may include forming structures on a semiconductor substrate, which may include both depositing and removing material. Method 10 is described below with respect to FIG. 2B, FIGS. 3A-3D, FIGS. 4A-4C, and 5A-5C, which depict specific stages of fabrication of semiconductor structures in accordance with one or more embodiments of the present disclosure. The method 10 may be part of a multi-step fabrication process of a semiconductor device. Accordingly, the method 10 may be performed in any suitable processing chamber coupled to a cluster tool. The cluster tool, as illustrated in FIG. 6, may include process chambers for fabricating a semiconductor device, such as chambers configured for etching, deposition, epitaxial growth, physical vapor deposition (PVD), chemical vapor deposition (CVD), oxidation, or any other suitable chamber used for the fabrication of a semiconductor device. In one or more embodiments, the method may be performed in a processing chamber or cluster tool without breaking vacuum.

Method 10 may or may not involve optional operations to develop the semiconductor structure to a particular fabrication operation. It is to be understood that method 10 may be performed on any number of semiconductor devices 300 or substrates 302, as illustrated in FIGS. 3A-3D, including exemplary structures on which a selective deposition material may be formed. As illustrated in FIG. 3A, substrate 302 may have a number of layers of material deposited overlying the substrate. Substrate 302 may be any number of materials, such as a base wafer or substrate made of silicon or silicon-containing materials, germanium, other substrate materials, as well as one or more materials that may be formed overlying the substrate during semiconductor processing.

Device 300 may illustrate a partial view of a substrate, which in embodiments may be used in n-channel and p-channel MOSFETs, FinFETs, gate-all-around FETs, complementary metal-oxide semiconductors, and nanosheet FETs, among other types of semiconductor transistor structures. The layers of material may be produced by any number of methods, including chemical vapor deposition (CVD), physical vapor deposition (PVD), atomic layer deposition (ALD), thermally enhanced chemical vapor deposition (TECVD), plasma-enhanced chemical vapor deposition (PECVD), plasma enhanced atomic layer deposition (PEALD), or any other formation technique. In embodiments, plasma-enhanced chemical vapor deposition may be performed in a processing chamber. Substrate layers can include silicon oxide and silicon nitride, silicon oxide and silicon, silicon nitride and silicon, silicon and doped silicon, or any number of other materials.

As illustrated in FIG. 3A, structure 300 is provided that includes a substrate 302 that has already undergone source/drain 304 formation. In embodiments, source/drain 304 formation may include epitaxial growth of a doped silicon material such as a silicon-germanium material. Although, it should be understood that the source/drain region 304 may be formed from any suitable deposition and patterning process, as the present technology does not require stringent source/drain 304 formation (e.g., attempts to cure epitaxial growth defects) to maintain hole or electron mobility. In addition, structure 300 contains a plurality of gate regions 306 and interlayer dielectric/dummy gate region 308, which may be formed as known in the art and discussed above.

In some embodiments, the substrate 302 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 302 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 302 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the present technology may provide improved mobility in both p- and n-type semiconductors. In one or more embodiments, however, p-type semiconductors may experience further improved hole mobility.

Referring to FIG. 1 and FIG. 3A, operation 12 of method 10 may include patterning one or more mask layers 310 deposited on the substrate 302 on the upper surface of the source/drain regions 304 and a portion of gate regions 306. In one or more embodiments, as illustrated, one or more mask layers 310 are patterned above five of the seven illustrated gate regions 306, leaving two gate regions 306 exposed. It should be understood that the patterned mask layers 310 may be disposed above one or more gates regions 306 or spaced apart at intervals as necessary to provide the necessary stress on channel regions 316.

As illustrated in FIG. 3B, at operations 14 and 16, method 10 may include etching the device 300. For example, in one or more embodiments, one or more of inductively coupled plasma (ICP) etching, reactive ion etching (RIE), or capacitively coupled plasma (CCP) etching is used to form shallow trench isolation or via 312. Furthermore, as the mask layers 310 are aligned with gate regions 306, the shallow trench isolations 312 may be formed in and self-aligned with a gate region, and thus considered to be self-aligned shallow trench isolations or self-aligned diffusion breaks. Furthermore, as shown, in FIG. 3B, the self-aligned diffusion break opening 312 defines a volume from structure upper surface 332 to a bottom 334 of self-aligned diffusion break opening 312. In one or more embodiments, the diffusion break opening 312 has a bottom surface and at least one sidewall surface.

In one or more embodiments, the self-aligned diffusion break opening 312 has an aspect ratio of greater than 8, including an aspect ratio of greater than 10. In some embodiments, the aspect ratio of the diffusion break 312 is greater than or equal to about 10:1, 15:1, 20:1, 25:1, 30:1, 35:1 or 40:1. In one or more embodiments the aspect ratio is greater than 25:1. Additionally, the self-aligned diffusion break opening 312 may have a narrow width or diameters across the feature including between two sidewalls, such as a dimension less than or about 100 nm, and may have a width across the feature of less than or about 90 nm, less than or about 80 nm, less than or about 70 nm, less than or about 60 nm, less than or about 50 nm, less than or about 40 nm, less than or about 30 nm, less than or about 20 nm, less than or about 17 nm, less than or about 15 nm, less than or about 12 nm, less than or about 10 nm, less than or about 9 nm, less than or about 8 nm, less than or about 7 nm, less than or about 6 nm, less than or about 5 nm, or less.

After etching operations 14 and 16, the device 300 may optionally undergo passivation and/or oxidation at operation 18, and removal of mask layers 310, as shown in FIG. 3C.

Referring to FIG. 3D, in one or more embodiments, at operation 20, the self-aligned diffusion break opening 312 is filled with a stressed dielectric material 314. In one or more embodiments, using a stressed dielectric material 314 in the self-aligned diffusion break opening 312, the compressive stress is transferred from the stressed dielectric material 314 to the adjacent channel regions without suffering from channel stress relaxation.

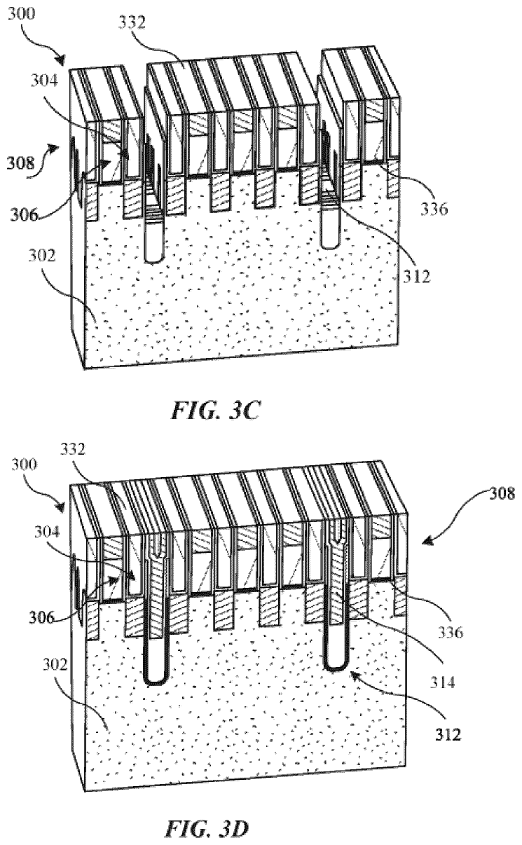

FIGS. 4A-4C illustrate cross-sectional views of a portion of the device illustrated in FIGS. 3A-3D. More specifically, FIGS. 4A-4C illustrate the self-aligned diffusion break opening 412 being filled with a dielectric layer 414, e.g., a nitride material, adjacent to the active region/nanosheet region 420 of the device 400. In one or more embodiments, the self-aligned diffusion break opening 412 can be gap filled according to any suitable process known to the skilled artisan. In one or more embodiments, the self-aligned diffusion break opening 412 is partially filled, as illustrated in FIGS. 4A-4B, using a densified seam-free compressive silicon nitride (SiN) gap fill process with bottom-up capability and then, referring to FIG. 4C, is filled the rest of the way using atomic layer deposition (ALD) of silicon nitride (SiN).

Referring to FIG. 1 and FIG. 4A, in one or more embodiments of method 10, at operation 20, a silicon-containing layer 414, is deposited in the self-aligned diffusion break opening 412 of the device 400. In one or more embodiments, the silicon-containing layer 414, e.g., amorphous silicon, is formed on the bottom surface of the diffusion break opening 412. One or more silicon-containing precursors can be flowed into a processing chamber via a delivery device.

In some embodiments, the silicon-containing precursor is an organosilicon compound. For example, the organosilicon compound can include a compound having silicon, hydrogen, and/or a combination thereof. In one or more embodiments, the organosilicon compound can include silane. In one or more embodiments, the silicon-containing precursors may include one or more silicon-containing precursors, as well as one or more diluents or carrier gases such as an inert gas or other gas delivered with the silicon-containing precursor. Silicon-containing precursors that may be used during the formation of the silicon-containing layer 414 may include, but are not limited to, silane (SiH₄), disilane (Si₂H₆), trisilane (Si₃H₈), tetrasilane (Si₄H₁₀), pentasilane (Si₅H₁₂), or other organosilanes including cyclohexasilanes, silicon tetrafluoride (SiF₄), silicon tetrachloride (SiCl₄), dichlorosilane (SiH₂Cl₂), tetraethyl orthosilicate (TEOS), as well as any other silicon-containing precursors that may be used in silicon-containing dielectric layer 414 formation.

The silicon-containing precursors may be delivered to a surface of the substrate at a flow rate of about 5 sccm to about 5000 sccm, e.g., about 5 sccm to about 250 sccm, about 250 sccm to about 1000 sccm, about 1000 sccm to about 2000 sccm, about 2000 sccm to about 3000 sccm, about 3000 sccm to about 4000 sccm, or about 4000 sccm to about 5000 sccm. The surface of the substrate can be about 40° C. and about 150° C., e.g., about 40° C. to about 60° C., about 60° C. to about 80° C., about 80° C. to about 100° C., about 100° C. to about 120° C., about 120° C. to about 140° C., or about 140° C. to about 150° C. The pressure of the processing chamber can be about 0.5 Torr to about 3 Torr, e.g., about 0.5 Torr to about 1 Torr, about 1 Torr to about 2 Torr, or about 2 Torr to about 3 Torr.

In some embodiments the silicon-containing precursor may be delivered to the surface of the substrate using a carrier gas, e.g., argon (Ar), hydrogen (H₂), helium (He), or a combination thereof. In one or more embodiments, the carrier gas may be delivered at a flow rate of about 250 sccm to about 5000 sccm, e.g., about 250 sccm to about 1000 sccm, about 1000 sccm to about 2000 sccm, about 2000 sccm to about 3000 sccm, about 3000 sccm to about 4000 sccm, or about 4000 sccm to about 5000 sccm.

In one or more embodiments, a flow ratio of about 1:100 to about 1:500 of silicon-containing precursor to carrier gas, e.g., about 1:100 to about 1:125, about 1:125 to about 1:166, or about 1:166 to about 1:500. Without intending to be bound by theory, a higher ratio of carrier gas to silicon-containing precursor can increase selective deposition of the silicon-containing precursor to the bottom of the diffusion break opening 412. In one or more embodiments, the silicon-containing precursor may be delivered to produce an amorphous silica layer formed on and/or over the diffusion break opening 412.

Deposition plasma effluents may be formed of the deposition precursors including the silicon-containing precursor. The deposition plasma effluents may be formed within the processing region, which may allow deposition materials to deposit on the substrate. For example, in some embodiments a capacitively-coupled plasma may be formed within the processing region by applying plasma power.

The power applied during deposition may be a lower power plasma, which may limit dissociation, and which may maintain an amount of hydrogen incorporation in the deposited materials. Accordingly, in some embodiments a plasma power source may deliver a plasma power of less than or about 300 W and may deliver a power of less than or about 250 W, less than or about 200 W, less than or about 150 W, less than or about 100 W, less than or about 50 W, or less. At plasma powers of greater than, for example, 350 W, the substrate, such as the sidewalls defining the diffusion break opening 412, may be damaged.

During the deposition operation, an additional power source, a bias power source, may be engaged and coupled to provide a bias to the plasma generated above the substrate. The bias may draw plasma effluents to the substrate, which may increase deposition at the bottom of the diffusion break opening 412. The bias power applied may be relatively low to limit damage to the device. Accordingly, in some embodiments a bias power source may deliver a plasma power of less than or about 1,000 W and may deliver a power of less than or about 750 W, less than or about 600 W, less than or about 500 W, less than or about 400 W, or less. Additionally, by adjusting the source power and the bias power applied, densification of the deposited silicon-containing material may occur during the deposition operation. In embodiments, both the source power and the bias power may be applied.

In one or more embodiments, a silicon-containing layer 414 may be deposited on the substrate from plasma effluents of the silicon-containing precursor. The silicon-containing material may be or include amorphous silicon. The deposited materials may at least partially fill the diffusion break opening 412 on the substrate to provide a bottom-up type of gap fill.

As illustrated in FIG. 4A, silicon-containing layer 414 may be deposited at the bottom of the diffusion break opening 412. In other unillustrated embodiments, silicon-containing layer 414 may be deposited at the bottom of the diffusion break opening 412, as well as above the diffusion break opening 412 on the substrate and on the sidewalls of the diffusion break opening 412. Although the amount of silicon-containing layer 414 deposited on the sidewalls may be relatively small or thin, continued formation may cause the diffusion break opening 412 to be pinched off. If pinched off, the formation of a seam or void in the material may occur as the gap fill continues. Accordingly, a series of depositions and etches, as further described below, may be performed to deposit seam-free silicon-containing layer 414 in the diffusion break opening 412.

Subsequent to an amount of deposition, in some embodiments a treatment or modification process may be formed that is configured to etch back the formed material. This process may be performed in the same processing chamber as the deposition and may be performed in a cyclic process to partially fill the diffusion break opening 412. In some embodiments, the silicon-containing precursor flow may be halted, and the processing region may be purged. Subsequent a purge, a hydrogen-containing precursor may be provided to the processing region. Treatment plasma effluents may be formed, which may also be a capacitively-coupled plasma formed within the processing region, although in some embodiments an inductively coupled plasma may similarly be applied. The treatment plasma effluents may be formed by applying a plasma power, and in some embodiments no other power source may be engaged.

Similar to the deposition operation, during the treatment operation, the bias power source may be engaged to provide a bias to the plasma generated above the substrate. This may draw plasma effluents to the substrate, which may bombard the film and cause densification of the deposited silicon-containing layer 414. Although any hydrogen-containing material may be used, in some embodiments diatomic hydrogen or deuterium may be used as the hydrogen-containing precursor to produce the treatment plasma, along with one or more additional precursors. The hydrogen radicals and ions may readily penetrate the materials formed within the diffusion break opening 412 and may release incorporated hydrogen from the silicon-containing layer 414 causing densification. The bias power applied may be relatively low to limit sputtering of the produced film as well as to limit any potential damage to the device. Materials delivered to form the plasma may similarly have a reduced amount of heavier materials to limit sputtering of the deposited films. Additionally, by adjusting the source power and the bias power applied, an etching operation may be performed, which may reduce sidewall coverage of the deposited material.

In one or more embodiments, plasma effluents may etch the silicon-containing layer 414 and may remove the silicon-containing layer 414 from the sidewalls of the diffusion break opening 412. The plasma effluents may fully remove silicon-containing layer 414 from the sidewalls of the diffusion break opening 412 above a base fill of the silicon-containing layer 414. The base fill of the silicon-containing material may refer to the silicon-containing layer 414 deposited at the bottom of the features diffusion break opening 412, as illustrated in FIG. 4A, or on the previously deposited silicon-containing layer 414 toward the bottom of the diffusion break opening 412. In embodiments, a ratio of silicon-containing layer 414 at the bottom of the feature relative to the sidewall, subsequent etching, may be greater than or about 1:1, such as greater than or about 2:1, greater than or about 3:1, greater than or about 4:1, greater than or about 5:1, greater than or about 6:1 or more. Due to the depth of the diffusion break opening 412, silicon-containing layer 414 at the bottom of the feature may be etched less due to plasma effluents not reaching the material.

Simultaneously, or additionally, plasma effluents delivered more directionally may penetrate the remaining silicon-containing layer 414 formed at the bottom of the diffusion break opening 412 and/or on the substrate. This penetration may reduce hydrogen incorporation to densify the film. In one or more embodiments, densifying the modified silicon-containing layer 414 includes reducing the hydrogen content of the modified silicon-containing layer 414 to less than about 30 atomic %. The densification may result from the plasma effluents of one or more precursors or, in embodiments, may be a separate operation using, for example, an inert precursor to densify the remaining silicon-containing layer 414. In one or more embodiments, silicon-containing material may be removed from sidewalls of the diffusion break, from overhang regions of the substrate, and/or from an upper surface of the substrate. This removal may maintain the deposited silicon-containing layer 414 at bottom regions of the diffusion break. The process may also provide a reduced hydrogen incorporation in the remaining material, such as a hydrogen incorporation of less than or about 40 atomic %, and may provide a reduced hydrogen incorporation of less than or about 35 atomic %, less than or about 30 atomic %, less than or about 25 atomic %, less than or about 20 atomic %, less than or about 15 atomic %, less than or about 10 atomic %, less than or about 5 atomic %, or less.

The etch operation may be performed halogen-free. In one or more embodiments, the etching is performed in a halogen-free process. The presence of halogen-containing materials may result in halogen residues remaining in the diffusion break opening 412 subsequent filling of the diffusion break opening 412 with silicon-containing layer 414. This halogen residue may contaminate the structure 400 and may cause non-uniformities to result during further processing. Accordingly, the etch operation may be performed without the presence of halogens or halogen-containing materials.

In one or more embodiments, the hydrogen-containing precursor may react with the silicon-containing layer 414 to form Si—H, Si—Si, and Si—H₂ at the surface of the silicon-containing layer 414 to form a modified silicon-containing layer 414m, as illustrated in FIG. 4B.

In some alternative embodiments, a thermal etching process may be performed on the modified silicon-containing layer 414m. The thermal etching process can include flowing a fluorine-containing compound, such as hydrogen fluoride (HF), nitrogen trifluoride (NF₃), or a combination thereof, over the modified amorphous silica layer at a temperature of about 400° C. to about 600° C., e.g., about 400° C. to about 450° C., about 450° C. to about 500° C., about 500° C. to about 550° C., or about 550° C. to about 600° C. For example, the thermal etching process can include flowing NF₃ over the modified amorphous silica layer at a temperature of about 450° C. In one or more embodiments, the temperature of about 400° C. to about 600° C. may allow for the NF₃ to act as a strong oxidizing agent, reacting with the Si—Si and Si—H₂ bonds at the surface of the modified silicon-containing layer 414m to form a uniform layer of Si—H bonds. Without intending to be bound by theory, a uniform layer of Si—H bonds may allow for single layers of Si—H to be nitrated to Si—N—H, Si—N₂, or Si—N, as described below, to promote uniform deposition of a dielectric films on the substrate.

The fluorinated compound may be delivered to the substrate at a flow rate of about 500 sccm to about 3000 sccm, e.g., about 500 sccm to about 1000 sccm, about 1000 sccm to about 2000 sccm, or about 2000 sccm to about 3000 sccm. The fluorinated compound may be delivered for a period of about 5 seconds(s) to about 60 s, e.g., about 5 s to about 10 s, about 10 s to about 20 s, about 20 s to about 40 s, or about 40 s to about 60 s. Alternatively, the fluorinated compound may be delivered for a period of greater than 60 s. The pressure of the processing chamber during the thermal etching process can be about 4 Torr to about 6 Torr, e.g., about 4 Torr to about 4.5 Torr, about 4.5 Torr to about 5 Torr, or about 5 Torr to about 6 Torr.

Without intending to be bound by theory, the thermal etching process may prevent and/or reduce defects from forming at the surface of the modified silicon-containing layer 414m, increasing uniformity on the feature of the substrate. Moreover, the thermal etching process may form a uniform layer of Si—H bonds, reducing and/or eliminating the need for an argon plasma etching step, while maintaining the film quality of the SiN dielectric film 415.

In one or more embodiments, one or more radicals (also referred to as a reactive gas) in the substrate processing region react with the modified silicon-containing layer 414m to form a silicon nitride SiN-based dielectric film 415. The radicals may be generated by a plasma generated in a remote plasma source (RPS) outside the processing chamber. The radicals may be flowed into a substrate processing region of the processing chamber along with a carrier gas (e.g., Ar, He). The plasma can be generated by the dissociation of a processing precursor gas including molecular oxygen (O₂), ozone (O₃), molecular hydrogen (H₂), a nitrogen-hydrogen compound (e.g., NH₃, N₂H₄), a nitrogen-oxygen compound (e.g., NO, NO₂, N₂O), a hydrogen-oxygen compound (e.g., H₂O, H₂O₂), a nitrogen-hydrogen-oxygen compound (e.g., NH₄OH), a carbon-oxygen compound (e.g., CO, CO₂), a fluorine-containing compound (e.g., NF₃), or a combination thereof. In the plasma, O*, H*, F*, and/or N*-containing radicals may be activated, such as O*, H*, F*, N*, NH₃*, N₂H₄*, NH₂*, NH*, N*O*, C₃H₆*, C₂H₂*, or a combination thereof.

In one or more embodiments, the ion energy of the radicals may be about 25 eV to about 70 eV, e.g., about 25 eV to about 40 eV, about 40 eV to about 60 eV, or about 60 eV to about 70 eV. Without intending to be bound by theory, an ion energy of the radicals that is about 25 eV to about 70 eV may reduce defect formation, e.g., bubbles, in the SiN based dielectric film 415. In one or more embodiments, the dosage value of the radicals may be about 1×10²⁰ ion/cm² to about 6×10²⁰ ion/cm² during the plasma treatment, e.g., about 1×10²⁰ ion/cm², to about 2×10²⁰ ion/cm², about 2×10²⁰ ion/cm², to about 3×10²⁰ ion/cm², about 3×10²⁰ ion/cm², to about 4×10²⁰ ion/cm², about 4×10²⁰ ion/cm², to about 5×10²⁰ ion/cm², or about 5×10²⁰ ion/cm², to about 6×10²⁰ ion/cm². Without intending to be bound by theory, dosage value of the radicals that is about 1×10²⁰ ion/cm², to about 6×10²⁰ ion/cm² may reduce defect formation, e.g., bubbles, in the SiN-based dielectric film.

In some embodiments, the radicals activated in the RPS are flowed into the processing chamber (referred to as “radical flux”) at a flow rate between about 1 sccm and about 10000 sccm. The composition of the formed SiN-based dielectric film can be adjusted by changing the composition of the reactive gas in the radical flux. To form a nitrogen-containing film, such as SiON, SiCON, and SiN films, the reactive gas may be, for example, ammonia (NH₃), hydrogen (H₂), hydrazine (N₂H₄), nitrogen dioxide (NO₂), or nitrogen (N₂). Without being bound by theory, when the reactive gas in the substrate processing region reacts with the delivered silicon-containing precursor, Si—H and N—H bonds (weaker bonds) are partially broken and replaced by Si—N, Si—NH, and/or Si—NH₂ bonds (stronger bonds) to form a SiN-dielectric film.

The formed silicon nitride (SiN)-based dielectric film can be exposed to a plasma containing light ions (e.g., ionized species having small atomic numbers in the periodic table), such as argon (e.g., Ar), nitrogen (e.g., N₂), or fluorine-containing compounds, (e.g., NF₃) in a plasma chamber to promote selective etching of the top of the gap. The plasma chamber is coupled to two power sources, an RF power source, which controls density of ion flux (also referred to as ion dose), via inductive coils and a DC bias, which controls ion energy.

The RF source can have a power of about 40 watts (W) to about 60 W, e.g., about 40 W to about 45 W, about 45 W to about 50 W, about 50 W to about 55 W, or about 55 W to about 60 W, when operating at a very high frequency of about 20 MHz to about 30 MHz, e.g., about 20 MHz to about 22 MHZ, about 22 MHz to about 24 MHZ, about 24 MHz to about 26 MHZ, about 26 MHz to about 28 MHZ, or about 28 MHz to about 30 MHz during the plasma treatment. In one or more embodiments, the plasma may have a power of about 50 Hz when operating at a frequency of about 27 MHz.

The DC bias can have a voltage of about 0.1 kV to about 10 KV, about 0.1 kV to about 8 kV, about 0.1 kV to about 7 kV, about 0.1 kV to about 6 kV, about 0.1 kV to about 5 kV, about 0.1 kV to about 4 KV, about 0.1 kV to about 2 KV, about 0.1 KV to about 1 KV, about 0.1 kV to about 0.5 kV, about 1 KV to about 10 KV, about 1 kV to about 8 kV, about 1 KV to about 7 kV, about 1 kV to about 6 kV, about 1 kV to about 5 kV, about 1 kV to about 4 kV, about 3 kV to about 10 KV, about 3 kV to about 8 kV, about 3 kV to about 7 kV, about 3 kV to about 6 kV, or about 3 kV to about 5 KV during the plasma treatment.

In some embodiments, a fluorine-containing compound, such as HF, NF₃, or a combination thereof, may be introduced to the chamber to promote selective etching of the top of the diffusion break opening 412. The fluorine-containing compound may be introduced at a flow rate of about 5 sccm to about 500 sccm, e.g., about 5 sccm to about 50 sccm, about 50 sccm to about 100 sccm, about 100 sccm to about 300 sccm, or about 300 sccm to about 500 sccm. The fluorine-containing compound may be introduced at a pressure of about 0.1 Torr to about 3 Torr, e.g., about 0.1 Torr to about 1 Torr, about 1 Torr to about 2 Torr, or about 2 Torr to about 3 Torr. The fluorine-containing compound may be introduced for a period of about 1 s to about 60 s, e.g., about 1 s to about 20 s, about 20 s to about 40 s, or about 40 s to about 60 s. The fluorine-containing compound may be introduced at a temperature of about 400° C. to about 600° C., e.g., about 400° C. to about 450° C., about 450° C. to about 500° C., about 500° C. to about 550° C., or about 550° C. to about 600° C. In one or more embodiments, the temperature of about 400° C. to about 600° C. may allow for the NF₃ to selectively etch the SiN-based dielectric film 415 at a top of the diffusion break opening 412, with minimal and/or no etching of the SiN-based dielectric film 415 at a bottom of the diffusion break opening 412.

The formed silicon nitride (SiN)-based dielectric film 415 can be exposed to a recovery process. The recovery process can include a hydrogen, e.g., H₂, recovery process. In one or more embodiments, hydrogen may react with the plasma treated SiN dielectric film 415 to remove one or more defects and/or bubbles on the SiN dielectric film 415. In one or more embodiments, the recovery process can include exposing the plasma treated SiN-based dielectric film to a recovery plasma. A recovery plasma includes a plasma containing one or more hydrogen ions, e.g., H*, in a plasma chamber. The hydrogen ion may be introduced at a flow rate of about 500 sccm to about 2500 sccm, e.g., about 500 sccm to about 1000 sccm, about 1000 sccm to about 1500 sccm, about 1500 sccm to about 2000 sccm, or about 2000 sccm to about 2500 sccm. The hydrogen ion may be introduced at a pressure of about 0.1 Torr to about 3 Torr, e.g., about 0.1 Torr to about 1 Torr, about 1 Torr to about 2 Torr, or about 2 Torr to about 3 Torr. The hydrogen ion may be introduced for a period of about 1 s to about 60 s, e.g., about 1 s to about 20 s, about 20 s to about 40 s, or about 40 s to about 60 s. The hydrogen ion may be introduced at a temperature of about 400° C. to about 600° C., e.g., about 400° C. to about 450° C., about 450° C. to about 500° C., about 500° C. to about 550° C., or about 550° C. to about 600° C. In one or more embodiments, the hydrogen ions may react with the SiF₄ bonds formed as a result of the NF₃ plasma treatment, causing Si—H bonds to form.

In one or more embodiments, the exposure to the recovery plasma in conjunction with the hydrogen ions can cause further cross-linking between the formed Si—H bonds and the N—H bonds in the formed SiN-based dielectric film. Without intending to be bound by theory, it is believed that radicals of hydrogen ions activated in the plasma may physically bombard Si—H bonds within the SiN-based dielectric film, thereby breaking the Si—H bonds and causing formation of Si—N, Si—NH, and/or Si—NH₂ bonds. The hydrogen ions travel through the formed SiN-based dielectric film to a selected depth without substantially damaging the formed SiN-based dielectric film. This treatment by radicals of the hydrogen ions makes it possible to remove one or more defects and/or bubbles formed from the NF₃ plasma etching process increasing the homogeneity to a depth ranging from 1 nm to 5 nm, such as from 3 nm to 4 nm, without damaging the formed SiN-based dielectric film 415.

The plasma chamber is coupled to two power sources, an RF power source, which controls density of ion flux (also referred to as ion dose), via inductive coils and a DC bias, which controls ion energy. The RF source can have a power of about 200 watts (W) to about 300 W, e.g., about 200 W to about 220 W, about 220 W to about 240 W, about 240 W to about 260 W, about 260 W to about 280 W, or about 280 W to about 300 W, when operating at a very high frequency of about 20 MHz to about 30 MHZ, e.g., about 20 MHz to about 22 MHZ, about 22 MHz to about 24 MHZ, about 24 MHz to about 26 MHz, about 26 MHz to about 28 MHz, or about 28 MHz to about 30 MHz. during the plasma treatment. In one or more embodiments, the plasma may have a power of about 240 Hz when operating at a frequency of about 27 MHz.

The DC bias can have a voltage of about 0.1 kV to about 10 KV, about 0.1 kV to about 8 kV, about 0.1 kV to about 7 kV, about 0.1 kV to about 6 kV, about 0.1 kV to about 5 KV, about 0.1 kV to about 4 KV, about 0.1 kV to about 2 kV, about 0.1 kV to about 1 KV, about 0.1 kV to about 0.5 kV, about 1 kV to about 10 KV, about 1 KV to about 8 kV, about 1 KV to about 7 kV, about 1 KV to about 6 kV, about 1 kV to about 5 kV, about 1 KV to about 4 KV, about 3 kV to about 10 KV, about 3 kV to about 8 kV, about 3 kV to about 7 kV, about 3 KV to about 6 kV, or about 3 kV to about 5 KV during the plasma treatment.

Referring to FIG. 1 and FIG. 4C, in one or more embodiments of the method 10, at operation 22, the remaining portion of the self-aligned diffusion break opening 412 may then be filled with a second dielectric material 416, e.g., nitride material, on top of the SiN-based dielectric film 415 to fill the self-aligned diffusion break opening 412. The second dielectric material 416 may comprise any suitable dielectric material known to the skilled artisan. In one or more embodiments, the second dielectric material 416 comprises silicon nitride (SiN).

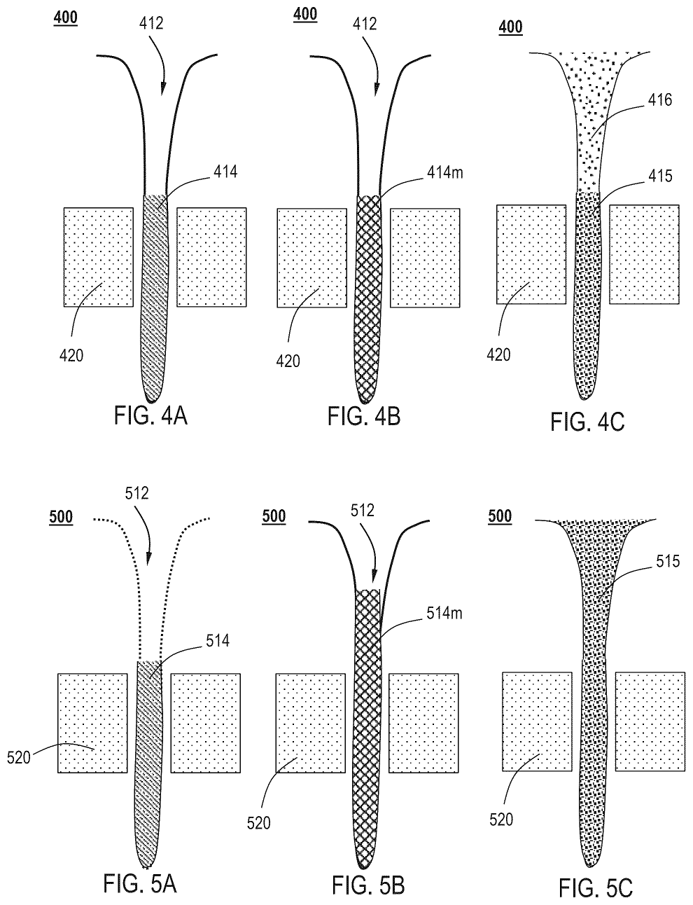

FIGS. 5A-5C illustrate cross-sectional views of a portion of the device illustrated in FIGS. 3A-3D. More specifically, FIGS. 5A-5C illustrate the self-aligned diffusion break 512 being filled with a dielectric material 515, e.g., a nitride material, adjacent to the active region/nanosheet region 520 of the device 500. In one or more embodiments, the self-aligned diffusion break 512 can be gap filled according to any suitable process known to the skilled artisan. In one or more embodiments, the self-aligned diffusion break 512 is filled completely, as illustrated in FIGS. 5A-5C, using the densified seam-free compressive silicon nitride (SiN) gap fill process with bottom-up capability described above with respect to FIGS. 4A and 4B and operation 20 of FIG. 1.

With reference to FIG. 1, in one or more embodiments, at operation 24, after the self-aligned diffusion break opening 312, 412, 512 is filled with a dielectric material, the device may be polished using any suitable technique known to the skilled artisan. In some embodiments, the device may be polished using chemical mechanical polishing (CMP) a top surface of the device 300 (FIG. 3D). The device 300 may then be subjected to further processing including, but not limited to, operation 26 replacement metal gate processing.

In one or more embodiments, the semiconductor device 300 having a self-aligned diffusion break opening 312 with an aspect ratio greater than 8 advantageously has substantially no void/intrinsic seam in the diffusion break gap fill 314 across the active device/nanosheet region leading to improved stress in the channel region.

In one or more unillustrated embodiments, there may be one type of device, e.g., NMOS, on a first portion of a wafer and a second type of device, e.g., PMOS, on a second portion of a wafer. Each of the devices may have a diffusion break that can be gap filled according to the processes disclosed herein. In one or more embodiments, the gap fill material may comprise any suitable dielectric material or metal and may have compressive or tensile stress. In some embodiments, the diffusion break opening may be filled with a compressive stress material on one portion of the substrate with one type of device, e.g., NMOS or PMOS, which can have channel mobility improvement due to the compressive stress gap fill, and a another portion of the substrate with another device, e.g., PMOS or NMOS, may be gap filled with a tensile stress material resulting in improved channel mobility due to the tensile stress gap fill. In one or more embodiments, localized stress modulation may be achieved by one or more additional patterning steps.

FIG. 6 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). In other embodiments, it is desired that the wafers be exposed to the ambient environment between processing steps, as will be detailed below.

In one or more embodiments, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers. Any suitable processing system known to the skilled artisan may be used.

In the illustrated example of FIG. 6, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some embodiments, the processing chamber 120 can be capable of performing an annealing process, the processing chamber 122 can be capable of performing a cleaning process, and the processing chambers 124, 126, 128, 130 can be capable of performing epitaxial growth processes. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be any suitable preclean chamber known to the skilled artisan. The processing chamber 120 may be any suitable etch chamber known to the skilled artisan.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
etching a diffusion break in a gate region of a semiconductor device, the diffusion break including a bottom surface and a sidewall surface, the gate region comprising an active region, the semiconductor device including a substrate, a source region, a drain region, and a channel extending between the source region and the drain region;
flowing a silicon-containing precursor and a carrier gas over the substrate to form a silicon-containing layer on the bottom surface of the diffusion break;
flowing a hydrogen-containing precursor over the silicon-containing layer to form a modified silicon-containing layer;
etching the modified silicon-containing layer from the sidewall of the diffusion break; and
reacting the modified silicon-containing layer with one or more radicals generated by a remote plasma source to form a silicon nitride (SiN) dielectric layer that at least partially fills the diffusion break.

2. The method of claim 1, wherein flowing a silicon-containing precursor comprises forming plasma effluents of the silicon-containing precursor and flowing the plasma effluents over the substrate.

3. The method of claim 1, wherein flowing the hydrogen-containing precursor comprises forming plasma effluents of the hydrogen-containing precursor and flow the plasma effluents over the substrate.

4. The method of claim 1, further comprising densifying the modified silicon-containing layer, wherein densifying comprises reducing hydrogen content of the modified silicon-containing layer to less than about 30 atomic %.

5. The method of claim 1, further comprising depositing a dielectric layer on the silicon nitride (SiN) dielectric layer by atomic layer deposition (ALD) to fill the diffusion break.

6. The method of claim 1, wherein the silicon nitride (SiN) dielectric layer completely fills the diffusion break.

7. The method of claim 1, wherein the active region is selected from a PMOS region or an NMOS region.

8. The method of claim 1, wherein the etching comprises flowing a fluorine-containing compound over modified silicon-containing layer at a temperature in a range of from 400° C. to 600° C.

9. The method of claim 8, wherein the fluorine-containing compound comprises nitrogen trifluoride (NF₃) and is flowed at a flow rate of about 500 sccm to about 3000 sccm.

10. The method of claim 1, wherein the diffusion break has an aspect ratio greater than 8:1.

11. The method of claim 1, wherein the etching is performed in a halogen-free process.

12. A method of forming a semiconductor device, the method comprising:
etching a diffusion break in a gate region of a semiconductor device, the diffusion break including a bottom surface and a sidewall surface, the gate region comprising an active region, the semiconductor device including a substrate, a source region, a drain region, and a channel extending between the source region and the drain region;
forming plasma effluents of a silicon-containing precursor and flowing the plasma effluents of the silicon-containing precursor over the substrate to form a silicon-containing layer on the bottom surface of the diffusion break;
forming plasma effluents of a hydrogen-containing precursor and flowing the plasma effluents of the hydrogen-containing precursor over the silicon-containing layer to form a modified silicon-containing layer;
etching the modified silicon-containing layer from the sidewall of the diffusion break;
densifying remaining modified silicon-containing layer within the diffusion break; and
reacting the modified silicon-containing layer with one or more radicals generated by a remote plasma source to form a silicon nitride (SiN) dielectric layer that at least partially fills the diffusion break.

13. The method of claim 12, wherein densifying comprises reducing hydrogen content of the modified silicon-containing layer to less than about 30 atomic %.

14. The method of claim 12, further comprising depositing a dielectric layer on the silicon nitride (SiN) dielectric layer by atomic layer deposition (ALD) to fill the diffusion break.

15. The method of claim 12, wherein the silicon nitride (SiN) dielectric layer completely fills the diffusion break.

16. The method of claim 12, wherein the one or more radicals comprise hydrogen (H*) radicals.

17. The method of claim 12, wherein the etching comprises flowing a fluorine-containing compound over modified silicon-containing layer at a temperature in a range of from 400° C. to 600° C.

18. The method of claim 12, wherein the etching is performed in a halogen-free process.

19. The method of claim 17, wherein the fluorine-containing compound comprises nitrogen trifluoride (NF₃).

20. A method of forming a semiconductor device, the method comprising:
etching a first diffusion break opening in a first gate region of a first semiconductor device on a first portion of a substrate, the first diffusion break opening including a first bottom surface and a first sidewall surface, the first semiconductor device including a first source region, a first drain region, and a first channel extending between the first source region and the first drain region;
etching a second diffusion break opening in a second gate region of a second semiconductor device on a second portion of the substrate, the second diffusion break opening including a second bottom surface and a second sidewall surface, the second semiconductor device including a second source region, a second drain region, and a second channel extending between the second source region and the second drain region;
gap filling the first diffusion break opening with a first dielectric layer having a compressive stress; and
gap filling the second diffusion break opening with a second dielectric layer having a tensile stress.

21. The method of claim 20, wherein the first semiconductor device comprises an NMOS device and the second semiconductor device comprises a PMOS device.
